(19) United States
(12) Patent Application Publication
(10) Pub. No.: US 2003/0197249 A1
(43) Pub. Date: Oct. 23, 2003

(54) Contactable integrated circuit and method of producing such a circuit

(76) Inventor: Thomas Doderer, Munchen (DE)

Correspondence Address: LERNER AND GREENBERG, P.A., POST OFFICE BOX 2480, HOLLWOOD, FL, 33022-2480, US

(21) Appl. No.: 10/417,568

(22) Filed: Apr. 17, 2003

(30) Foreign Application Priority Data
Apr. 17, 2002 (DE) 102 16 873.3

(51) Int. Cl. H01L 39/00

(52) U.S. Cl. 257/662

(57) ABSTRACT

In an integrated circuit on a substrate material with a terminal area for contacting the integrated circuit, the integrated circuit includes a contact area for the connection of the integrated circuit to external lines. A stripline for transmitting high-frequency signals is provided between the contact area and the terminal area.

### BACKGROUND OF THE INVENTION

### Field of the Invention

The invention relates to an integrated circuit that can be connected to external lines by a contact area. The invention also relates to a method of producing such an integrated circuit.

The increasing popularity of mobile devices is responsible, in particular, for the requirement that the integrated circuits contained therein should be lightweight and small in size. One of the ways in which these characteristics can be achieved is by reducing the size of the housing or package or by providing what are referred to as wafer level packages (WLPs), which substantially no longer have a housing of their own and include only the integrated circuits produced on a substrate. For contacting these WLPs, contact areas that are located on the surface of the substrate and are in electrical connection with the integrated circuit are provided.

Wafer level packages are produced by processing the entire wafer so as to obtain after sawing the wafer ready-“packaged” components, which can be mounted substantially without further process steps. To produce WLPs from the chips in which the integrated circuits are disposed, rerouting of the wiring is necessary to allow contacting of the terminal areas (pads) disposed on the integrated circuit, which are in direct connection with the electronic circuit. This is necessary because the terminal areas in the integrated circuit are so small that it is only possible with considerable effort for them to be contacted externally, for example, by solder bumps, connecting wires, or the like. In addition, because they were produced by planar production processes, these terminal areas are very sensitive to mechanical influences. As a result, they have to be protected in a special way. For such a purpose, the terminal areas of the integrated circuit are connected to conductor connections, which lead to contact areas.

The contact areas are larger than the terminal areas and are largely resistant to external mechanical and other influences.

These wafer level packages are usually mounted on module boards, which have what are referred to as contact bumps. The contact areas are, therefore, disposed with a spacing that is based on the spacing of the contact bumps of the module boards. This spacing is, generally, considerably greater than the spacing of the terminal areas on the integrated circuit. Because the integrated circuits are contacted by the wiring lines, all the electrical signals to the chip and from the chip are transmitted by these lines. Because the wiring lines take the form of simple lines, there may be a deterioration in the signal quality, in particular, in the high-frequency range, for example, due to crosstalk, attenuation, dispersion, transit time, and so on.

This occurs, in particular, in the case of particularly long line connections, as caused by a length that is of the order of magnitude of the chip dimensions.

To counteract the deterioration in the signal quality, it is usually envisaged to make the individual wiring lines of the same length. In such a case, however, only the differences in transit times of the individual lines are minimized, but other impairments of the signal quality are left uninfluenced.

### SUMMARY OF THE INVENTION

It is accordingly an object of the invention to provide a contactable integrated circuit and method of producing such a circuit that overcomes the hereinafore-mentioned disadvantages of the heretofore-known devices and methods of this general type and, in which, the signal quality when transmitting by the wiring line is impaired as little as possible.

With the foregoing and other objects in view, there is provided, in accordance with the invention, a circuit assembly including a substrate material, an integrated circuit disposed on the substrate material and formed as a wafer level package, a terminal area contacting at least a portion of the integrated circuit, a contact area disposed on the integrated circuit for connecting of the integrated circuit to external lines, and an integrated stripline for transmitting high-frequency signals, the stripline being provided in an integrated form between the contact area and the terminal area.

Accordingly, the invention provides an integrated circuit that has a terminal area for contacting the integrated circuit on a substrate material. The integrated circuit also has a contact area, to connect the integrated circuit to external lines or to contact bumps of a module board. Provided between the contact area and the terminal area is a stripline for transmitting high-frequency signals.

As is known, striplines are lines that are suitable for transmitting high-frequency signals. They generally have two conductors led in parallel, one of which is, preferably, associated with a fixed potential, but may also be potential-free, i.e., without connection to a potential source.

Using striplines for the wiring minimizes impairments of the signal quality. In particular, edge steepness, attenuation, and crosstalk can be reduced if a stripline is used.

The use of a stripline for the wiring lines in a wafer level package is advisable, in particular, because the wiring lines are of a length that is of the order of magnitude of the chip dimensions and, for such a reason, is significant for the high-frequency signal transmission.

In accordance with another feature of the invention, there is provided an insulating layer that bears the contact area to be disposed on the integrated circuit, the stripline being formed on the insulating layer as a coplanar stripline. A coplanar stripline is understood as meaning a stripline that has two conductor tracks led in parallel, which are disposed next to each other with respect to the surface of the substrate material. This has the advantage that the stripline can be produced in a single process step, that is, applying the metallization to the insulating layer.

In accordance with a further feature of the invention, the stripline is formed by the conductor connection and a further conductor structure disposed vertically in relation to the conductor connection. To achieve the vertical configuration of the conductors of the stripline, a dielectric layer is, preferably, disposed between the conductor connection and the conductor structure. Such a configuration has the advantage that the lines are disposed very close together, in particular, when there are a relatively large number of terminal areas or contact areas of the integrated circuit. As a result, there is substantially insufficient space available to provide coplanar striplines.

In accordance with an added feature of the invention, there are provided a conductor connection to the terminal area forming the stripline, an insulating layer disposed on the integrated circuit, the contact area and the conductor connection being disposed on the insulating layer, and a conductor structure disposed vertically in relation to the conductor connection, the conductor structure to be connected to a given voltage potential.

In accordance with an additional feature of the invention, there are provided a conductor connection to the terminal area forming the stripline, an insulating layer disposed on substrate material, the contact area and the conductor connection being disposed on the insulating layer, and a conductor structure disposed vertically in relation to the conductor connection, the conductor structure to be connected to a given voltage potential.

In accordance with yet another feature of the invention, there is provided a dielectric layer disposed between the conductor connection and the conductor structure.

In accordance with yet a further feature of the invention, a conductive layer is disposed over the conductor connection and an aperture is provided for contacting the contact area.

In accordance with yet an added feature of the invention, the conductive structure is disposed over the conductor connection and the dielectric layer defines an aperture contacting the contact area.

In accordance with yet an additional feature of the invention, preferably, the substrate material is made larger than is necessary for receiving the integrated circuit. The substrate material, in such a case, has a first region, in which the integrated circuit is disposed, and a second region, which has no effective elements. The terminal area is provided in the first region and the contact area is provided substantially over the second region. This has the advantage when a number of contact areas are provided of making the spacing of the contact areas sufficiently large to reduce the influence of high-frequency signals on neighboring contact areas or line connections.

With the objects of the invention in view, in a circuit assembly having a substrate material and an integrated circuit formed as a wafer level package on the substrate material, there is also provided a connection configuration including a terminal area contacting the integrated circuit, a contact area disposed on the integrated circuit for connecting the integrated circuit to external lines, and an integrated stripline for transmitting high-frequency signals, the stripline being provided in an integrated form between the contact area and the terminal area.

With the objects of the invention in view, there is also provided an integrated circuit formed as a wafer level package on a substrate material, including a terminal area for contacting the integrated circuit, a contact area for connecting the integrated circuit to external lines, the contact area being disposed on the integrated circuit, and an integrated stripline for transmitting high-frequency signals, the stripline being provided in an integrated form between the contact area and the terminal area.

According to a further aspect of the present invention, a production method for a contactable integrated circuit is provided. The production method envisages applying a dielectric layer to the integrated circuit and disposing thereon a contact area that can be connected by a conductor connection to the terminal area of the integrated circuit. A stripline is formed by disposing a conductor structure such that it is isolated from the conductor connection. The conductor structure is, preferably, provided such that it has substantially the same spacing over the entire length of the conductor connection.

With the objects of the invention in view, there is also provided a method of producing a contactable integrated circuit, including the steps of providing an integrated circuit with a terminal area, applying a non-electrical layer to the integrated circuit, applying a contact area at the integrated circuit, applying a conductor connection connecting the terminal area to the contact area, and disposing a conductor structure at the integrated circuit isolated from the conductor connection to form with the conductor connection a stripline.

With the objects of the invention in view, there is also provided a method of producing a contactable integrated circuit having a terminal area, including the steps of applying a non-electrical layer, applying a contact area, applying a conductor connection in order to connect the terminal to the contact area, and disposing a conductor structure such that it is isolated from the conductor connection, in order to form with the conductor connection a stripline.

In accordance with again another mode of the invention, the step of disposing the conductor structure is carried out by applying a dielectric layer over the conductor connection and applying the conductor structure on the dielectric layer.

In accordance with a concomitant feature of the invention, at least one of the steps of applying the contact area, applying the conductor connection, and applying the conductor structure is carried out with sputtering or vapor depositing.

The production method allows a wafer level package that is particularly suitable for high-frequency signals to be provided in a particularly simple way. In particular, when producing a coplanar stripline, the conductor connection and the conductor structure can be produced in one process step. As a result, there is no additional expenditure in production when producing wafer level packages capable of operating at high frequency.

Other features that are considered as characteristic for the invention are set forth in the appended claims.

Although the invention is illustrated and described herein as embodied in a contactable integrated circuit and method of producing such a circuit, it is, nevertheless, not intended to be limited to the details shown because various modifications and structural changes may be made therein without departing from the spirit of the invention and within the scope and range of equivalents of the claims.

The construction and method of operation of the invention, however, together with additional objects and advantages thereof, will be best understood from the following description of specific embodiments when read in connection with the accompanying drawings.

### BRIEF DESCRIPTION OF THE DRAWINGS

FIGS. 1A to 1G are diagrammatic, side elevational views of examples of various types of striplines according to the invention;

FIG. 2 is a plan view of an integrated circuit according to one embodiment of the invention;

FIG. 3 is a fragmentary, cross-sectional view of a portion of the embodiment of FIG. 2 along sectional line III-III;

FIG. 4 is a plan view of an integrated circuit with a vertical stripline according to a further embodiment of the invention; and

FIG. 5 is a fragmentary cross-sectional view of a portion of the circuit of FIG. 4 along sectional line V-V.

### DESCRIPTION OF THE PREFERRED EMBODIMENTS

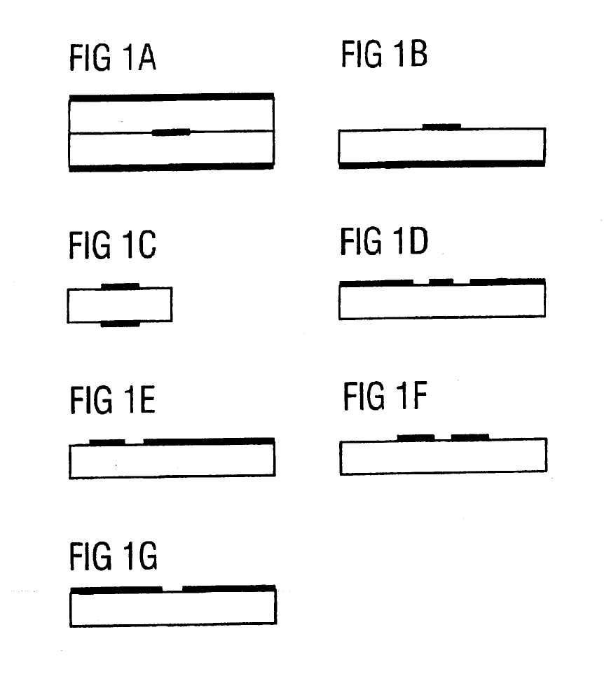

Referring now to the figures of the drawings in detail and first, particularly to FIGS. 1A to 1G thereof, there are shown various configurations of striplines. FIGS. 1A to 1C show vertically constructed striplines, the stripline represented in FIG. 1A being a shielded stripline.

Various coplanar striplines are represented in FIGS. 1D to 1G, both symmetrical and unsymmetrical.

In a stripline, high-frequency electrical signals are passed between two conductor tracks. Serving, in this case, as the transmission medium is the dielectric disposed between the conductors.

The type of stripline may be selected according to the type of signal transmission (time-invariant or high-frequency). Striplines generally impair the signal quality less than the conventional single-wire lines in the high-frequency range (in particular, frequencies above about 100 MHz). What is more, the crosstalk between lines is minimized.

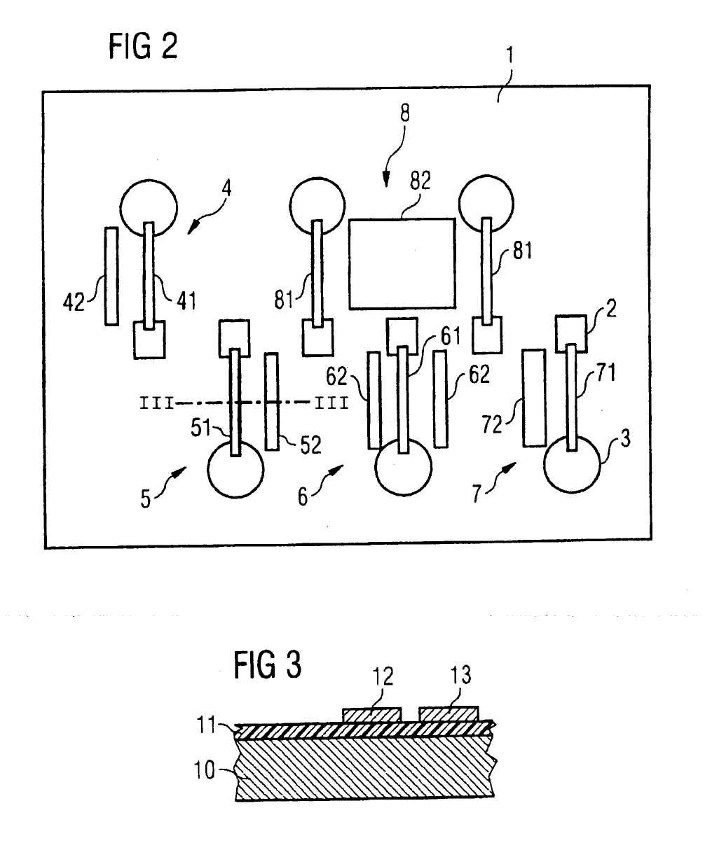

A first embodiment of the invention is represented in FIG. 2, which shows a plan view of an integrated circuit 1 with terminal pads 2, which are in direct connection with the integrated circuit and are produced substantially by a planar process with the conductor tracks of the integrated circuit. Also provided are contact areas 3, by which the integrated circuit can be connected to external contacting devices. Such contacting devices may be solder bumps, cable connections, or the like.

Striplines are disposed respectively between the terminal pads 2 and the contact areas 3. Depending on the type of signals preferably to be transmitted there, the striplines take different forms. Represented in FIG. 2 are various types of coplanar striplines, which connect terminal pads 2 and contact areas 3. Simple two-band lines 4, 5 may be disposed between the terminal pads 2 and the contact areas 3. These substantially include a direct line connection 41, 51 between the terminal pads 2 and the contact area 3. Disposed substantially parallel thereto is a further conductor structure 42, 52, which, however, is not in connection with the corresponding terminal pad 2 and the corresponding terminal area 3. The further conductor structure 42, 52 is, preferably, connected to a fixed potential, in particular, to a ground potential. The further conductor structure 42, 52 may also be potential-free, i.e., it is without connection to further electrically active components.

If very high-frequency signals are transmitted, a shielded stripline 6 is necessary. By contrast with the simple coplanar striplines 4, 5, the shielded stripline 6 has a conductor structure 62 on both sides of the conductor connection 61 between the terminal pad 2 and the contact area 3 and the respective structures are led substantially parallel to the conductor connection 61.

As represented in the case of the unsymmetrical stripline 7, a conductor structure 72 may have virtually any desired width if the edge lying opposite the conductor connection 71 runs substantially parallel to the conductor connection 71.

The unsymmetrical stripline 8 may also be formed by a sheet-like conductor structure 81, outer edges of the conductor structure 81 running parallel to two or more line connections 81 between terminal pads 2 and contact areas 3. The sheet-like conductor structure 82 is connected to a fixed potential or is kept potential-free and, consequently, serves, at the same time, as a shielding area with respect to integrated circuits disposed thereunder. The conductor structure 82 effectively shields electromagnetic radiation emitted by the integrated circuit from the regions lying thereabove and similarly prevents electromagnetic radiation from acting on the integrated circuit.

The coplanar stripline has the advantage that it represents low expenditure in production in comparison with the conventional single-wire line. Such wiring lines have the advantage, however, in particular, in the case of wafer level packages, and, more particularly, in the case of lines in which high-frequency signals are transmitted, that a distinct improvement is achieved in the transmitted signal quality. As a result, a higher yield of serviceable circuits can be expected. Moreover, the upper cut-off frequency with which a chip so constructed can be operated is shifted distinctly upward. In addition, the quality of the signal sent to the chip, in particular, the amplitude of the signal, is expected to meet lower requirements because lower signal losses occur during the transmission. The same similarly applies to the output signals that are generated in the integrated circuit on the chip.

The additional expenditure during production of the wiring lines lies only in the setting of a new mask layout for the metallization level, with which the terminal pads 2 are connected to the contact areas 3.

In addition, the striplines allow the integration of further passive components, such as, for example, filters, directional couplers, transformers, or branches. These can be produced simply by corresponding structuring of the layers that define the stripline.

In FIG. 3, a cross-section along the section line III-III is represented. The integrated circuit is, in this case, constructed in the substrate 10. Over the integrated circuit there is an insulating layer 11, on which the connecting lines or the conductor structures have been applied.

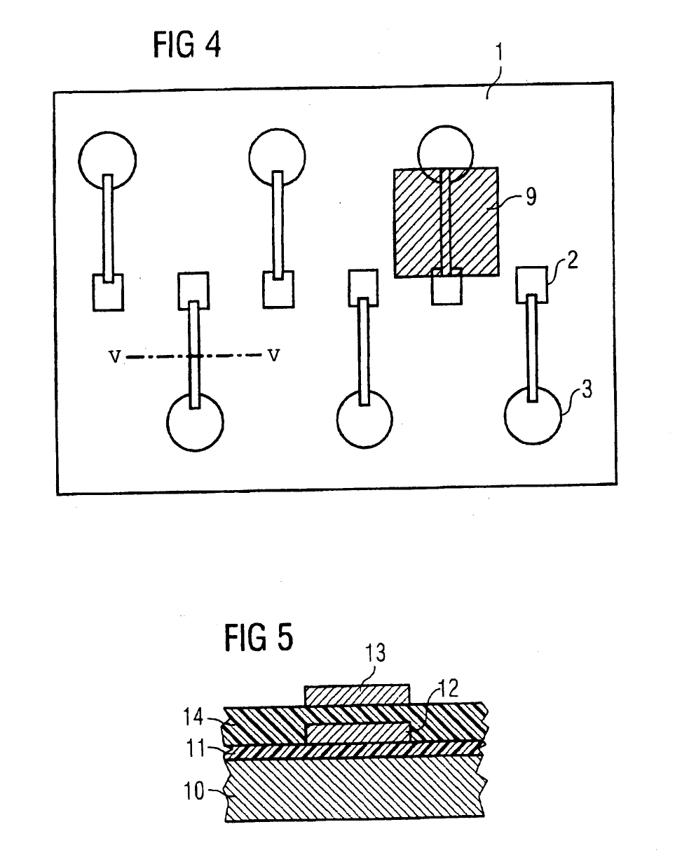

In FIG. 4, a further embodiment of the present invention is represented. As before, conductor connections are routed between the terminal pads 2 and the contact areas 3. In order to form a stripline, parallel to these connections there are conductor structures, not parallel in a horizontal plane as in the previous exemplary embodiment, but formed vertically above the respective conductor connection. Between the conductor connection and the conductor structure there is, preferably, a dielectric, which has a dielectric constant that is as small as possible, so that the capacitive coupling between the lines is minimized. What is more, the dielectric loss factor, which occurs at high frequencies in the dielectric, must be as small as possible.

The conductor structure may substantially have the same form as the conductor connection and be disposed vertically above the conductor connection with respect to the substrate surface.

It is also possible, however, for the conductor structure 9 to be formed in a sheet-like manner, as represented by the shaded area in FIG. 4, the area of the conductor structure being disposed at least partly over the conductor connection, as represented in region 9, in order to form a stripline. The sheet-like configuration of the conductor structure has the advantage, as already stated above, that integrated circuits can be protected from the effect of electromagnetic radiation and that the emission of electromagnetic radiation by the integrated circuit into the surroundings can be minimized.

In FIG. 5, a sectional diagram along a line V-V of a vertically constructed stripline is represented. The conductor connection 12 has been applied on an insulating layer 11 and connects the terminal pad 2 to the contact area 3. The contact area 3 can be contacted from the outside (not shown), i.e., the dielectric layer 14 applied over the connection line 12 has an aperture over the contact area 3. The dielectric layer 14 serves the purpose of forming a substantially equal spacing with respect to the conductor structure 13 substantially over the entire length and width. On the dielectric layer 14, the conductor structure is formed substantially such that it covers the conductor connection 12 virtually over the entire length, it having to be ensured that the conductor structure does not come into connection with the terminal pad 2, the conductor connection, and the contact area 3. The conductor structure 13 is, preferably, connected to a fixed potential, which is, in particular, a ground potential of the integrated circuit, but the conductor structure 13 may also be kept potential-free, i.e., freely “floating”.

To produce an integrated circuit that can be contacted in this way, a dielectric layer that has apertures over the terminal pad 2 is applied. Subsequently, contact areas 3 are applied, and conductor connections to connect the terminal pad 2 to the contact area 3. After that, a conductor structure 13 is applied such that it is isolated from the conductor connection 12, disposed so as to form with the conductor connection a stripline. For such a purpose, a further dielectric layer 14 is applied over the conductor connection so that a conductor structure deposited thereupon is disposed substantially with the same spacing over the entire length and width of the conductor connection as a result of the dielectric layer 14. It goes without saying that the method may also be organized such that the conductor structure lies underneath the conductor connection.

The contact area, the conductor connection and/or the conductor structure are to be deposited on the chip by a sputtering process, a vapor-depositing process, or an electrodepositing process. Thin-film depositing processes, such as, for example, sputtering, vaporizing, or chemical processes are suitable, in particular, for producing the dielectric layer 14, but other processes with which dielectric layers of the same thickness as far as possible can be produced may also be used.

In comparison with the coplanar configuration of the striplines, the vertically disposed striplines have the advantage that they require less surface area, which is advantageous, in particular, in the case of integrated circuits with many external connections. The vertical configuration of striplines has the further advantage, in particular, that special protection of the integrated circuit against electrostatic and mechanical influences is ensured by the additional dielectric layer, which is of significance, in particular, when the integrated circuit is used as a wafer level package.

Wafer level packages are usually of a size that is based on the integrated circuit. In particular, when there are a relatively large number of necessary contact areas for the contacting of the circuit, it may be necessary to provide more space for disposing the contact areas. This can be advantageously achieved by giving the substrate larger dimensions so that the integrated circuit takes up only part of the overall surface area of the chip. As a result, however, additional space is created for disposing the contact areas.

Moreover, it may be envisaged to provide contact areas on both sides of the substrate, in order to combine the wafer level package with other components in a sandwich assembly. For such a purpose, the conductor connections may be led from the front side of the substrate, on which the integrated circuit is disposed, to the rear side either around the cut edges or through the substrate.

I claim:

1. A circuit assembly, comprising:
a substrate material;
an integrated circuit disposed on said substrate material and formed as a wafer level package;
a terminal area contacting at least a portion of said integrated circuit;
a contact area disposed on said integrated circuit for connecting said integrated circuit to external lines; and
an integrated stripline for transmitting high-frequency signals, said stripline being provided in an integrated form between said contact area and said terminal area.

2. The assembly according to claim 1, further comprising an insulating layer disposed on said integrated circuit, said contact area being disposed on said insulating layer, said stripline being formed on said insulating layer as a coplanar stripline.

3. The assembly according to claim 1, further comprising an insulating layer disposed on said substrate material, said contact area being disposed on said insulating layer, said stripline being formed on said insulating layer as a coplanar stripline.

4. The assembly according to claim 1, further comprising:
a conductor connection to said terminal area forming said stripline;
an insulating layer disposed on said integrated circuit, said contact area and said conductor connection being disposed on said insulating layer; and
a conductor structure disposed vertically in relation to said conductor connection, said conductor structure to be connected to a given voltage potential.

5. The assembly according to claim 1, further comprising:
a conductor connection to said terminal area forming said stripline;
an insulating layer disposed on substrate material, said contact area and said conductor connection being disposed on said insulating layer; and
a conductor structure disposed vertically in relation to said conductor connection, said conductor structure to be connected to a given voltage potential.

6. The assembly according to claim 4, further comprising a dielectric layer disposed between said conductor connection and said conductor structure.

7. The assembly according to claim 5, further comprising a dielectric layer disposed between said conductor connection and said conductor structure.

8. The assembly according to claim 6, wherein:
a conductive layer is disposed over said conductor connection; and
an aperture is provided for contacting said contact area.

9. The assembly according to claim 7, wherein:
a conductive layer is disposed over said conductor connection; and
an aperture is provided for contacting said contact area.

10. The assembly according to claim 6, wherein:
said conductive structure is disposed over said conductor connection; and
said dielectric layer defines an aperture contacting said contact area.

11. The assembly according to claim 7, wherein:
said conductive structure is disposed over said conductor connection; and
said dielectric layer defines an aperture contacting said contact area.

12. The assembly according to claim 1, wherein:
said substrate material has a first region and a second region having no effective elements;
said integrated circuit is disposed in said first region;
said terminal area is disposed in said first region; and
said contact area is disposed substantially over said second region.

13. In a circuit assembly having a substrate material and an integrated circuit formed as a wafer level package on the substrate material, a connection configuration comprising:
a terminal area contacting the integrated circuit;
a contact area disposed on the integrated circuit for connecting the integrated circuit to external lines; and
an integrated stripline for transmitting high-frequency signals, said stripline being provided in an integrated form between said contact area and said terminal area.

14. An integrated circuit formed as a wafer level package on a substrate material, comprising:
a terminal area for contacting the integrated circuit;
a contact area for connecting the integrated circuit to external lines, said contact area being disposed on the integrated circuit; and
an integrated stripline for transmitting high-frequency signals, said stripline being provided in an integrated form between said contact area and said terminal area.

15. A method of producing a contactable integrated circuit, which comprises:
providing an integrated circuit with a terminal area;
applying a non-electrical layer to the integrated circuit;
applying a contact area at the integrated circuit;
applying a conductor connection connecting the terminal area to the contact area; and
disposing a conductor structure at the integrated circuit isolated from the conductor connection to form with the conductor connection a stripline.

16. The method according to claim 15, which further comprises carrying out the step of disposing the conductor structure by applying a dielectric layer over the conductor connection and applying the conductor structure on the dielectric layer.

17. The method according to claim 15, which further comprises carrying out at least one of steps of applying the contact area, applying the conductor connection, and applying the conductor structure with sputtering or vapor depositing.

18. A method of producing a contactable integrated circuit having a terminal area, which comprises:
applying a non-electrical layer;
applying a contact area;
applying a conductor connection in order to connect the terminal to the contact area; and
disposing a conductor structure isolated from the conductor connection to form with the conductor connection a stripline.

19. The method according to claim 18, which further comprises carrying out the step of disposing the conductor structure by applying a dielectric layer over the conductor connection and applying the conductor structure on the dielectric layer.

20. The method according to claim 18, which further comprises carrying out at least one of steps of applying the contact area, applying the conductor connection, and applying the conductor structure with sputtering or vapor depositing.
